(19) United States
(12) Patent Application Publication
(10) Pub. No.: US 2022/0413017 A1
(43) Pub. Date: Dec. 29, 2022

(54) MEASURING METHOD FOR DETERMINING THE CURRENT THROUGH A SHUNT RESISTOR

(71) Applicant: Battrion AG, Dubendorf (CH)

(72) Inventors: Martin EBNER, Kuesnacht (ZH) (CH); Deniz Bozyigit, Zuerich (CH)

(21) Appl. No.: 17/850,458

(22) Filed: Jun. 27, 2022

(30) Foreign Application Priority Data
Jun. 28, 2021 (DE) 10 2021 116 657.8

(51) Int. Cl. G01R 15/14; H02M 3/158

(52) U.S. Cl. CPC G01R 15/146; H02M 3/158

(57) ABSTRACT

What is proposed is a method for accurately determining an electric current (Iᵢₙ, I_{in,0}) with reduced technical outlay, comprising: connecting a circuit branch (2, 12) in parallel with an inaccurate but current-loadable shunt resistor (Rₛₕ), wherein a reference resistor (R_{ref}) that is more accurate in comparison with the shunt resistor (Rₛₕ) but less current-loadable is connected into the circuit branch (2, 12), such that the circuit branch (2, 12) branches off in each case at a node point (K) upstream and downstream of the shunt resistor, generating a temporally changeable reference current (I_{ref}, I′_{ref}, I″_{ref}) through the circuit branch (2, 12), measuring the voltages (V′ₛₕ, V″ₛₕ, V′_{ref}, V″_{ref}) across the shunt resistor (Rₛₕ) and across the reference resistor (R_{ref}), determining the current strength (Iᵢₙ, I_{in,0}) upstream and downstream of the node point (K).

### CROSS-REFERENCE TO RELATED APPLICATION

This application claims the benefit of German Application No. 10 2021 116 657.8, filed Jun. 28, 2021, the contents of which is hereby incorporated by reference in its entirety, further the entirety of the attached translation of German Application No. 10 2021 116 657.8 is incorporated by reference.

### FIELD OF THE DISCLOSURE

The present disclosure relates to a measuring device and to a measuring method for accurately determining an electric current, in particular, but not by limitation, in the case of high current strengths up to considerably beyond 1000 A.

### BRIEF SUMMARY

Various methods are known from the prior art for being able to measure or determine high current strengths. In order to determine AC currents, use is conventionally made for example of what is known as a Rogowski coil, in which a voltage is induced by the alternating field of a conductor flowed through by the AC current to be determined. In addition to the described direct measurement of the magnetic field, a determination may also be achieved through magnetic field compensation. Such a compensation current sensor for DC and AC currents operates for example using Hall sensors, as disclosed in DE 42 30 939 A1. A further sensor operating according to the compensation principle is a flux gate sensor, as described in EP 2 669 688 A1; the last sensor mentioned, what is known as a DCCT sensor, is however used for specific applications in connection with particle accelerators.

The object of the present disclosure is to provide a device and a method that allow precise determination of a current strength and are at the same time able to be implemented without any great technical outlay.

Based on a method and a device of the type mentioned at the outset, the object is achieved by the features of claim 1 and claim 6, respectively.

Advantageous embodiments and developments of the present disclosure are possible by way of the features mentioned in the dependent claims.

One particular application for which the present disclosure described below may be used is that of determining the Coulombic efficiency of lithium-ion batteries, by way of which the service life of a cell is able to be estimated well even after a short measurement duration. This is particularly advantageous since it is possible, by measuring Coulombic efficiency, to ascertain the influence of important factors such as temperature, charging current, operating strategy, etc. on the service life in a short time. One typical application is also that of accurately determining a resistance of a shunt resistor while this is being used for the current measurement.

An aspect of the present disclosure is based on the idea of determining the current strength by formulating it on the basis of variables that are able to be measured very precisely. Since the proposed device and the proposed method are however intended to measure very high current strengths of far more than 100 A, even beyond 1000 A, small systematic errors may however already destroy the accuracy of a measurement. Due to the magnitude of the current strength to be determined, direct measurements are barely possible. Furthermore, even small errors, for example due to a temperature drift of the inherent resistance of any ammeter, would already lead to unacceptable errors. Using an aspect of the present disclosure, it is possible for example to determine current strengths of 100 A with an accuracy of better than 1 mA.

According to an aspect of the present disclosure, a circuit branch is connected in parallel with an inaccurate but current-loadable shunt resistor, wherein the resistance of the shunt resistor may itself be determined at the same time as the determination. This circuit branch comprises a reference resistor that is as accurate as possible in comparison with the shunt resistor but less current-loadable, that is to say the reference resistor generally carries current strengths that are lower, in particular considerably lower than those with which the shunt resistor is loaded.
An aspect of the present disclosure for example has the advantage over a conventional Rogowski coil that the measurement accuracy is not dependent on the positioning of a coil in relation to the conductor and thus on the field distribution of a magnetic field.
Furthermore, when employing magnetic field measurements, as provided for inter alia by the Rogowski coil, there is a strong tendency for the measurement to be distorted by other external magnetic fields, in particular including by Earth's magnetic field. This interfering effect may also be ruled out according to an aspect of the present disclosure.
An aspect of the present disclosure furthermore makes it possible to measure DC currents since—unlike other sensors operating on an inductive basis—it is not necessary to generate any induction voltage. On the whole, the measurement results in an aspect of the present disclosure are also generally advantageously independent of the temporal current profile.
An aspect of the present disclosure additionally has the advantage that it is able to operate independently of any additional amplifier or integrator circuits with the associated disadvantages of (offset) stability, deviations from linear behavior, etc.
An aspect of the present disclosure also has the advantage that the current measurement is able to take place very quickly.

The parallel circuit forms a node point upstream and downstream of the shunt resistor.

In order to be able to form a system of equations in which for example the current strength upstream and downstream of the node point is formulated as a variable independent of the value of the unknown or at least not accurately known resistance of the shunt resistor, a temporally changeable reference current is generated through the circuit branch.

Two mutually opposing currents thus flow through the shunt resistor, namely:
the flow of current that branches off at the node point, wherein the part flowing through the shunt resistor is far greater than the part flowing through the reference resistor, and
the current generated by the reference current source, which (passes the node point) and flows back through the shunt resistor again.

This feature according to an aspect of the present disclosure makes it possible for example to formulate the current strength on the basis of the voltages that are dropped across the shunt resistor and the reference resistor and on the basis of the relatively accurately known resistance of the reference resistor. Voltage measurements are generally able to be performed very precisely. The inherent resistances of voltmeters are so high that the loss caused by a flow of current through the voltmeter is negligible.

The reference current is modified according to an aspect of the present disclosure in order to have enough variables to be able to solve the system of equations. One option for modifying the reference current is that of deactivating the circuit branch. This may be performed by a mechanical switch, but does not have to be. Instead, it is also possible to use an electronic switch, for example a transistor, especially a field-effect transistor, such that voltage peaks during switching, corroded contacts or the like are able to be avoided.

An additional reference current source may instead also be connected into the circuit branch. It is thereby possible to generate even more values than only pairs; accuracy may be increased.

In order to increase accuracy even further, further interfering sources may be eliminated by galvanically isolating the reference current source. A current source independent from the mains may be used for this purpose. It is also conceivable in principle to supply the current source with energy via an isolating transformer or a similar circuit. A current source that allows a stand-alone power supply is however completely independent. In one development of the present disclosure, a solar cell is very well-suited for this. In order to obtain a stable current source, the solar cell may be illuminated by a dedicated light source. What is proposed for example is a combination of a solar cell pre-mounted on a circuit board and a high-intensity infrared light-emitting diode (IR-LED). The current source is in this case completely galvanically isolated. Such a current source delivers high currents, including under short-circuit conditions.

In order to obtain a reference current with a modifiable current strength, the light source used to illuminate the solar cell may be modified. Two solar cells may furthermore also be illuminated independently of one another and switched or operated in opposition, such that the reference current strength and also the current direction are able to be changed by changing the brightness of one or both light sources. The two light sources may for example be illuminated alternately. If the parallel-connected circuit branch is intended to be disconnected in order to modify the current strength, then the circuit branch may also be routed via a transistor or via a field-effect transistor, which is then put into the off state by the flow of current of the solar cell.

In one advantageous embodiment of the present disclosure, a bridge circuit may be used to determine the resistance of the shunt resistor. The shunt resistor whose resistance is to be determined is connected into the bridge branch. A bridge circuit may also advantageously be used to reverse the polarity of the reference current. The resistance is determined by determining the current strengths in the sub-branches.

The reference current with alternating polarity may thereby be selected to be highly symmetrical about 0 V, making it possible to increase measurement accuracy. The polarity may be reversed very quickly and precisely, in particular in the case of switching using field-effect transistors.

The advantages of a bridge circuit could be those of enabling a more precise symmetry in the polarity reversal of the reference current or a more accurate 50% duty cycle. Only one solar cell is then also necessary in principle for the reference current source.

### Exemplary Embodiment

Exemplary embodiments of the present disclosure are illustrated in the drawings and are explained in more detail below with further details and advantages being given.

### BRIEF DESCRIPTION OF THE DRAWINGS

FIG. 1 shows a schematic circuit diagram of a measuring device according to one example with a circuit branch that is able to be connected in,

FIG. 2 shows a schematic circuit diagram of a measuring device according to one example with a changeable reference current source,

FIG. 3 shows a schematic circuit diagram for implementing the switch for a measuring device according to FIG. 1, and

FIG. 4-5 show schematic circuit diagrams for implementing the reference current source for measuring devices according to FIG. 2, here with solar cells for galvanic isolation.

### DETAILED DESCRIPTION

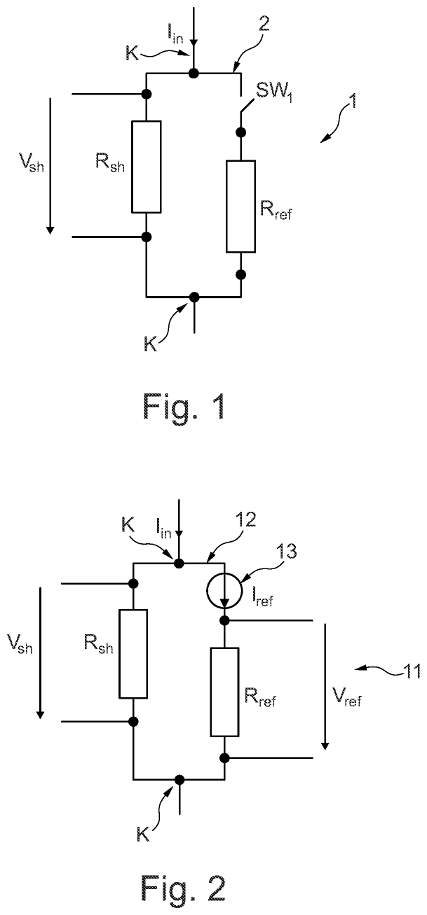

FIG. 1 shows a schematic circuit diagram of a measuring device 1 according to one example having a switch SW₁ for connecting in or disconnecting a circuit branch 2.

The situation in which the circuit branch 2 is connected in, that is to say the switch SW₁ is closed, is indicated by a “dash(′)”, and the situation with an open switch SW₁ is indicated by “two dashes(″)” in the variables. With an open switch SW₁:

I_{ref}″=0

With a closed switch SW₁:

I_{ref}′=I_{ref,0}

The resistances of the resistors, that is to say shunt resistor and reference resistor, are assumed to be constant for the short time between the switching alternations:

Rₛₕ′=Rₛₕ″=R_{sh,0}

and

R_{ref}′=R_{ref}″=R_{ref,0}

The circuit is also operated (the switching alternations are performed so quickly) that the current strengths Iᵢₙ may be assumed to be constant upstream and downstream of the node point at which the path into the branch through the shunt resistor and through the circuit branch containing the reference resistor branch, that is to say:

Iᵢₙ′=Iᵢₙ″=I_{in,0}

For closed switches SW₁, this gives:

$${V}_{sh}^{′} = \frac{{R}_{sh}^{′} \cdot {R}_{ref}^{′}}{{R}_{sh}^{′} + {R}_{ref}^{′}} {I}_{in}^{′} = \frac{{R}_{sh , 0} \cdot {R}_{ref , 0}}{{R}_{sh , 0} + {R}_{ref , 0}} {I}_{in , 0}$$

while with an open switch SW₁:

Vₛₕ″=Rₛₕ″·Iᵢₙ″=R_{sh,0}·I_{in,0}

This ultimately gives overall for Iᵢₙ:

$${V}_{sh}^{′} = \frac{\frac{{V}_{sh}^{″}}{{I}_{in , 0}} \cdot {R}_{ref , 0}}{\frac{{V}_{sh}^{″}}{{I}_{in , 0}} + {R}_{ref , 0}} {I}_{in , 0} \to {I}_{in , 0} = \frac{1}{{R}_{ref , 0}} \cdot \frac{{V}_{sh}^{′} \cdot {V}_{sh}^{″}}{( {V}_{sh}^{″} - {V}_{sh}^{′} )}$$

The calculation is performed here assuming that the switch SW₁ behaves like a mechanical switch and has a practically infinitely large resistance in the open state and has no ohmic resistance in the closed state.

For the rest, high current strengths Iᵢₙ should generally be expected.

FIG. 2 shows an embodiment similar to FIG. 1 (measuring device 11), but in which the flow of current through the circuit branch 12 is not completely interrupted, but rather in which the polarity of the reference current I_{ref} alternates (phase 1, identified by a “dash(′)”, in reversal to phase 2, identified by a “dash(″)”, that is to say

I_{ref}′=+I_{ref,0}

and

I_{ref}″=−I_{ref,0}

For this purpose, use is made of a current source 13 that is connected into the circuit branch 12 in series with the reference resistor R_{ref} and whose polarity is able to be alternated. The flow of current is furthermore set such that Iᵢₙ remains constant, that is to say:

Iᵢₙ′=Iᵢₙ″=I_{in,0}

Regardless of the circuit situation, the resistance of the shunt resistor and reference resistor is assumed to be constant for the short time between the switching alternations, that is to say

Rₛₕ′=Rₛₕ″=R_{sh,0}

and

R_{ref}′=R_{ref}″=R_{ref,0}

This ultimately gives, for the two phases with different polarity of the reference current strength:

Vₛₕ′=(Iᵢₙ′−I_{ref}′)·Rₛₕ′=(I_{in,0}−I_{ref,0})·R_{sh,0}

V_{ref}′=I_{ref}′·R_{ref}′=I_{ref,0}·R_{ref,0}

and

Vₛₕ″=(Iᵢₙ″−I_{ref}″)·Rₛₕ″=(I_{in,0}−I_{ref,0})·R_{sh,0}

V_{ref}″=I_{ref}″·R_{ref}″=I_{ref,0}·R_{ref,0}

Rearrangements ultimately give:

$$\frac{{V}_{ref}^{′} - {V}_{ref}^{″}}{2 {R}_{ref , 0}} = \frac{{I}_{ref , 0} \cdot {R}_{ref , 0} + {I}_{ref , 0} \cdot {R}_{ref , 0}}{2 {R}_{ref , 0}} = {I}_{ref , 0}$$

and also

$$\frac{{V}_{sh}^{″} + {V}_{sh}^{′}}{{V}_{sh}^{″} - {V}_{sh}^{′}} = \frac{( {I}_{in , 0} + {I}_{ref , 0} ) \cdot {R}_{sh , 0} + ( {I}_{in , 0} - {I}_{ref , 0} ) \cdot {R}_{sh , 0}}{( {I}_{in , 0} + {I}_{ref , 0} ) \cdot {R}_{sh , 0} - ( {I}_{in , 0} - {I}_{ref , 0} ) \cdot {R}_{sh , 0}} = \frac{{I}_{in , 0}}{{I}_{ref , 0}}$$

from which the following is concluded for the current strength

$$\frac{{V}_{ref}^{′} - {V}_{ref}^{″}}{2 {R}_{ref , 0}} \cdot \frac{{V}_{sh}^{″} + {V}_{sh}^{′}}{{V}_{sh}^{″} - {V}_{sh}^{′}} = {I}_{in , 0}$$

This thus gives, to within a factor of ½, a formula similar to the exemplary embodiment according to FIG. 1.

The exemplary embodiments according to FIGS. 1 and 2 have the common feature that only voltages, which are also able to be measured very accurately, are required and have to be measured. The resistance of the reference resistor is likewise very accurately known.

It is also possible to accurately determine the measurement current I_{in,0} and the resistance R_{sh,0} of the shunt resistor when the absolute values of the reference current during the two phases are not identical, that is to say:

|I_{ref}′|≠|I_{ref}″|

The following relationships apply here:

$${I}_{ref}^{′} = \frac{{V}_{ref}^{′}}{{R}_{ref}^{′}} = \frac{{V}_{ref}^{′}}{{R}_{ref , 0}}$$

$${I}_{ref}^{″} = \frac{{V}_{ref}^{″}}{{R}_{ref}^{″}} = \frac{{V}_{ref}^{″}}{{R}_{ref , 0}}$$

$${R}_{sh , 0} = \frac{{V}_{sh}^{″} - {V}_{sh}^{′}}{( {I}_{in , 0} - {I}_{ref}^{″} ) - ( {I}_{in , 0} - {I}_{ref}^{′} )} = \frac{{V}_{sh}^{″} - {V}_{sh}^{′}}{{I}_{ref}^{′} - {I}_{ref}^{″}}$$

this gives:

$${R}_{sh , 0} = {R}_{ref , 0} \frac{{V}_{sh}^{″} - {V}_{sh}^{′}}{{V}_{ref}^{′} - {V}_{ref}^{″}}$$

Therefore, for each switching cycle, the current resistance of the shunt resistor may be determined purely from the measurable voltages and the known resistance of the reference resistor.

If the ascertained values of the resistance of the shunt resistor over multiple switching cycles, which are ascertained at times t=t₁, t=t₂, etc., are joined together, then it is possible to form a shunt resistor signal R_{sh,0}(t):

R_{sh,0}(t)={R_{sh,0}|t=t₁,R_{sh,0}|t=t₂ . . . }

It should be expected that this shunt resistor signal, due to noise in the voltage measurements for determining V′ₛₕ, V″ₛₕ, V′_{ref}, and V″_{ref}, will in turn contain noise, that is to say fast and small random changes. Since it should be expected that the resistance change, to be expected due to the heating of the shunt resistor caused by the current loading, will however take place relatively slowly, for example over a time interval of a few seconds, the shunt resistor signal may also be filtered in order to improve accuracy. Applying a filter function f to the shunt resistor signal R_{sh,0}(t) gives the filtered shunt resistor signal R*_{sh,0}(t):

R_{sh,0}*(t)=ƒ(R_{sh,0}(t))

An average filter, median filter, low-pass filter or other filter function common in signal processing may be used as suitable filter function f, for example.

The measurement current I_{in,0} may then be ascertained using the following equation:

$${I}_{in , 0} = \frac{1}{2} ( ( \frac{{V}_{sh}^{″}}{{R}_{sh , 0}^{*} ( t )} + {I}_{ref}^{″} ) + ( \frac{{V}_{sh}^{′}}{{R}_{sh , 0}^{*} ( t )} + {I}_{ref}^{′} ) )$$

$$Or :$$

$${I}_{in , 0} = \frac{1}{2} ( ( \frac{{V}_{sh}^{″}}{{R}_{sh , 0}^{*} ( t )} + \frac{{V}_{ref}^{″}}{{R}_{ref , 0}} ) + ( \frac{{V}_{sh}^{′}}{{R}_{sh , 0}^{*} ( t )} + \frac{{V}_{ref}^{′}}{{R}_{ref , 0}} ) )$$

The measuring device according to one example may thus be used:
to determine a current strength very accurately,
even when a very high current strength is involved,
and also to precisely measure the unknown resistance of the shunt resistor.

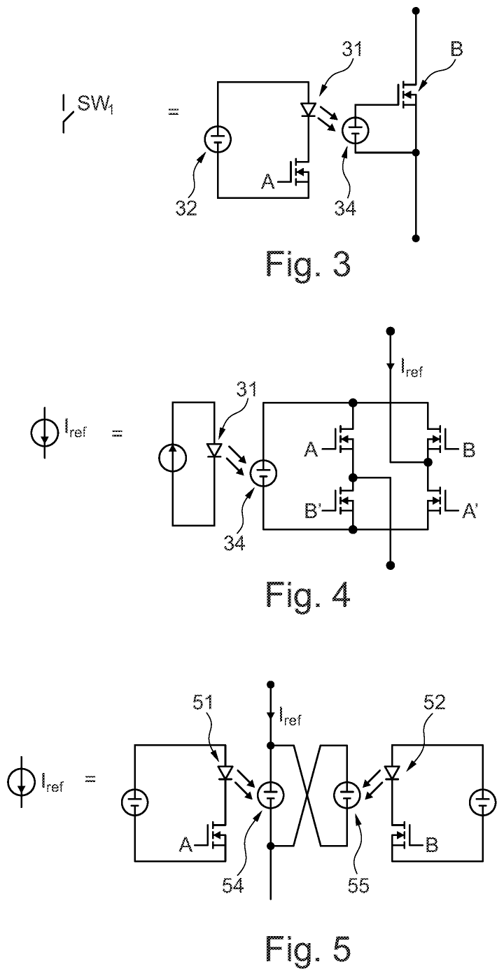

FIG. 3 shows a schematic illustration of how it is possible to implement the switch SW₁ that is required for the embodiment according to FIG. 1: The light-emitting diode 31 (emission in the infrared region) is supplied by a voltage source 32; the circuit is switched via the field-effect transistor A.

In order to perform complete galvanic isolation, a solar cell may for example be used as current source. In a manner similar to an optocoupler circuit, the light-emitting diode 31 illuminates a solar cell 34, which in turn switches a field-effect transistor B, such that this causes either the off state or the on state.

Finally, FIGS. 4 and 5 each show exemplary embodiments in which the reference current source 13 is able to be modified in terms of its current strength by alternating the polarity of the current. The variant embodiment according to FIG. 4 uses a bridge circuit (also called H circuit) to alternate the polarity. Depending on whether the field-effect transistor pairs A-A′ or B-B′ are respectively in the on state or off state, the current of the solar cell contributes to increasing or to reducing the reference current strength I_{ref}. In this case too, the solar cell 34 is illuminated by an infrared light-emitting diode. The switching in order to modify the reference current strength I_{ref} takes place solely through the transistors A-A′ or B-B′ in the circuit branch that also comprises the solar cell 34.

However, two solar cells 54, 55 could also be connected in antiparallel instead. From the point of view of the reference current I_{ref}, the polarity depends on which of the solar cells 54, 55 is illuminated.

Although the present invention has been described with reference to preferred embodiments, workers skilled in the art will recognize that changes may be made in form and detail without departing from the spirit and scope of the invention.

### LIST OF REFERENCE SIGNS

1 Measuring device
2 Circuit branch
11 Measuring device
12 Circuit branch
13 Reference current source
31 Light-emitting diode
32 Voltage source
34 Solar cell
51 Infrared light-emitting diode
52 Infrared light-emitting diode
54 Solar cell
55 Solar cell
A Field-effect transistor
A′ Field-effect transistor
B Field-effect transistor
B′ Field-effect transistor
I_{ref,0} Reference current strength
I_{ref}′ Reference current strength (phase 1)
I_{ref}″ Reference current strength (phase 2)
Iᵢₙ′ Current strength (phase 1)
Iᵢₙ″ Current strength (phase 2)
Iᵢₙ Current strength
I_{in,0} Current strength
K Node point
Rₛₕ′ Resistance of shunt resistor (phase 1)
Rₛₕ″ Resistance of shunt resistor (phase 2)
R_{sh,0} Resistance of shunt resistor
Rₛₕ Shunt resistor
R_{sh,0}(t) Shunt resistor signal
R_{sh,0}*(t) Filtered shunt resistor signal
ƒ Filter function
R_{ref}′ Resistance of reference resistor (phase 1)
R_{ref}″ Resistance of reference resistor (phase 2)
R_{ref,0} Resistance of reference resistor
R_{ref} Reference resistor
Vₛₕ′ Voltage across shunt resistor (phase 1)
Vₛₕ″ Voltage across shunt resistor (phase 2)
SW₁ Switch

What is claimed is:

1. A method for accurately determining an electric current, the method comprising:
connecting a circuit branch in parallel with an inaccurate but current-loadable shunt resistor, wherein a reference resistor that is more accurate in comparison with the shunt resistor but less current-loadable is connected into the circuit branch, such that the circuit branch branches off in each case at a node point upstream and downstream of the shunt resistor,
generating a temporally changeable reference current through the circuit branch,
measuring the voltages, across the shunt resistor and across the reference resistor, and
determining the current strength upstream and downstream of the node point.

2. The method of claim 1, wherein the reference current is modified by connecting in the circuit branch in parallel with the shunt resistor and disconnecting it again, and/or the voltages are measured with and without the circuit branch connected in.

3. The method of claim 1, wherein a reference current source is connected into the circuit branch and the flow of current in the circuit branch is thereby increased and the flow of current through the shunt resistor is reduced.

4. The method of claim 1, wherein the current strength upstream and downstream of the node point is kept constant even in the event of a temporal modification in the reference current through the circuit branch.

5. The method of claim 1, wherein a series of values for the resistance of the shunt resistor and/or the current strength is determined on the basis of the measured voltages that are dropped across the shunt resistor and the reference resistor and then filtered.

6. The method of claim 5, wherein the series of values are filtered using one or more of: an average filter, median filter, or a low-pass filter.

7. A measuring device for accurately determining an electric current, comprising a circuit that has an inaccurate but current-loadable shunt resistor and a circuit branch that is able to be attached and/or connected in parallel with the shunt resistor, wherein a reference resistor that is more accurate in comparison with the shunt resistor but less current-loadable and at least one switch and/or a current source for generating a reference current is connected into the circuit branch such that the flow of current at the node point at which the circuit branch is connected in parallel with the shunt resistor branches into the two paths through the shunt resistor and the reference resistor and a reference current is able to flow through the circuit branch, wherein the circuit branch is designed to bring about a temporally changeable reference current, wherein the measuring device is designed to measure the voltages that are each dropped across the shunt resistor and across the reference resistor in order therefrom to determine the current strength that flows towards and/or away from the respective node point at which the circuit branch branches off.

8. The measuring device of claim 7, wherein the circuit branch has a switch in order to interrupt and/or to activate the flow of current through the circuit branch in order thereby to bring about the temporally changeable reference current.

9. The measuring device of claim 7, wherein the circuit branch comprises a reference current source in order thereby to bring about the temporally changeable reference current.

10. The measuring device of claim 7, wherein the reference current source is connected in series with the reference resistor in the circuit branch in order thereby to bring about the temporally changeable reference current.

11. The measuring device of claim 7, wherein the switch is formed by at least one transistor, in particular a field-effect transistor.

12. The measuring device of claim 11, wherein the at least one transistor comprises a field-effect transistor.

13. The measuring device of claim 7, wherein the measuring device is designed such that the current strength upstream and downstream of the node point is kept constant even in the event of a temporal modification in the reference current through the circuit branch.

14. The measuring device of claim 7, wherein the reference current source is galvanically isolated.

15. The measuring device of claim 7, wherein the reference current source in the circuit branch contains at least one solar cell.

16. The measuring device of claim 15, wherein the at least one solar cell comprises a solar cell exposed to infrared radiation generated by a light-emitting diode (LED).

17. The measuring device of claim 7, wherein the temporally changeable reference current is generated by way of at least one switch.

18. The measuring device of claim 17, wherein the temporally changeable reference current is generated by multiple field-effect transistors in a bridge circuit comprising a current source that changes little over time.

19. The measuring device of claim 18, wherein the current source comprises a solar cell.

20. The measuring device of claim 7, wherein the reference current source is connected such that the flow of current in the circuit branch is increased and the flow of current through the shunt resistor is reduced.
